(19) United States
(12) Patent Application Publication
(10) Pub. No.: US 2023/0421149 A1
(43) Pub. Date: Dec. 28, 2023

(54) SEMICONDUCTOR SWITCH ASSEMBLY COMPRISING AT LEAST TWO POWER SEMICONDUCTORS

(71) Applicant: ZF Friedrichshafen AG, Friedrichshafen (DE)

(72) Inventors: Stefan HAIN, Speichersdorf (DE); Matthias LOCHNER, Bindlach (DE)

(73) Assignee: ZF Friedrichshafen AG, Friedrichshafen (DE)

(21) Appl. No.: 18/253,759

(22) PCT Filed: Nov. 15, 2021
(86) PCT No.: PCT/EP2021/081644

§ 371 Date: May 19, 2023

(30) Foreign Application Priority Data
Nov. 19, 2020 (DE) 10 2020 214 607.1

(51) Int. Cl. H03K 17/12; H02P 27/06

(52) U.S. Cl. CPC H03K 17/122; H02P 27/06; H03K 17/127

(57) ABSTRACT

The invention relates to a topological semiconductor switch for power electronics that has at least two power semiconductors, in particular power transistors, characterized in that the topological semiconductor switch has at least one first power semiconductor containing a first semiconductor material, and at least one second power semiconductor containing a second semiconductor material. The invention also relates to a motor vehicle.

The invention relates to a topological semiconductor switch that has at least two power semiconductors, in particular power transistors.

Inverters, also referred to as rectifiers, require a power module or semiconductor package with which direct current from a battery is converted to alternating current. The power module has topological switches containing power transistors with which the currents are controlled and the alternating current is generated. There are a variety of designs for these power transistors. Among others, MOSFETs (metal-oxide-semiconductor field-effect transistors) or IGBTs (insulated-gate bipolar transistors) can be used. The semiconductor material can be silicon (Si), silicon carbide (SiC), gallium nitride (GaN) or any other semiconductor material. The power modules have different forward characteristics, depending on the design of the power transistor and the semiconductor material.

Semiconductor transistors containing silicon have a better conductivity with larger currents, and semiconductor transistors containing silicon carbide have a better conductivity with smaller currents. The choice of semiconductor material in the semiconductor transistors can be made in accordance with the main operating range for which the inverter is intended.

Based on this, the object of the invention is to create a topological semiconductor switch that is more efficient and can be produced less expensively.

To solve this problem, a topological semiconductor switch of the type described above is proposed that has at least one first power semiconductor containing a first semiconductor material, and at least one second power semiconductor containing a second semiconductor material.

The core idea of the invention is to obtain a power semiconductor with at least two different semiconductor materials for power electronics when generating alternating current, and thus obtain an optimized power supply for the power electronics. There are at least two different power semiconductors in the topological switch. Consequently, the power semiconductor with the best range for a specific application can be used exclusively for that application. Alternatively, a portion of the power semiconductor can also be used in certain operating ranges.

Topological switches can be used to switch current or voltage. They can contain at least one power transistor, for example. They can also contain a diode. If the power transistor is not able to accommodate a predefined amount of current by itself, it is possible to connect numerous power transistors in parallel.

Power semiconductors can be designed as power transistors, power diodes, power multilayer diodes, power triodes, or as other power semiconductor components. A power diode can form a capacitor diode, switch diode, Schottky diode, rectifier diode, or Zenner diode. A power multilayer diode can be a four-layer diode. A power triode can be a thyristor, DIAC, or TRIAC. A power transistor can be a bipolar transistor or field-effect transistor, in particular a barrier FET or MOSFET. Furthermore, a power semiconductor can be a Darlington transistor or IGBT.

The power semiconductors are preferably power transistors.

There are preferably the same number of first power semiconductors as there are second power semiconductors. It is also possible to have more of one type of power semiconductor than the other. In this case, the majority of power semiconductors correspond to a power range established as the main power range.

It is advantageous if one of the semiconductor materials, in particular the first semiconductor material, is silicon (Si). Silicon is a semiconductor material that has better conductivity at higher currents.

It is advantageous if at least one power semiconductor, in particular the power transistor that contains the first semiconductor material, is an IGBT.

One of the semiconductor materials, in particular the second semiconductor material, can preferably be silicon carbide (SiC). This material is more efficient with lower currents.

At least one power semiconductor, in particular the power transistor containing the second semiconductor material, can preferably be a MOSFET.

It can therefore be the case that there are two types of power transistors, specifically power transistors with silicon and power transistors with silicon carbide. In this case, the power transistors containing silicon can be IGBTs, and the power transistors containing silicon carbide can be MOSFETs.

The power semiconductors can be power semiconductor switches, regardless of the semiconductor material that is used. In particular, the power transistors can be active switches. There can also be passive switches, e.g. diodes, in power electronics in the form of an inverter, but there should be at least two different types of active switches.

In particular, the power semiconductors can be configured for use in the positive current direction, i.e. toward the electric motor when used in an inverter. The topological switch therefore preferably has at least two different active switches for the positive current direction.

The reverse or negative current direction can be different, depending on the power semiconductor in the positive current direction. With power transistors that have silicon carbide, in particular MOSFETs with silicon carbide, the reverse current can pass through the same power transistors. With IGBTs that contain silicon, a diode can be placed in the negative current direction.

Gallium nitride (GaN) can also be used for the semiconductor material. Gallium oxide (Ga₂O₃) can also be used for the semiconductor material. Gallium arsenide (GaAs) can also be used for the semiconductor material. Carbon (C) can also be used for the semiconductor material.

Basically, any semiconductor material can be used for the first semiconductor material, and any other semiconductor material can be used for the second semiconductor material. A third and fourth semiconductor material can also be used if this results in further optimization. Each additional semiconductor results in greater complexity, however, because they require either additional inverters or printed circuit boards, and the control thereof becomes increasingly more complicated.

The more efficient power semiconductors, in particular power transistors, preferably provide at least 10% of the power in the power electronics in which they are incorporated, i.e. the inverter power, for example. The more efficient power semiconductors, in particular power transistors, can preferably provide at least 20%, at least 30%, or at least 40% of the power in the power electronics in which they are incorporated. Moreover, the more efficient power semiconductors, in particular power transistors, can provide at least 50% of the power in the power electronics in which they are incorporated. This can also be at least 60%.

Greater efficiency is obtained when one of the semiconductor materials that is used has an optimal operating point in the average expected use. By way of example, silicon carbide is particularly efficient with lower currents. This correlates to lower accelerations and/or lower driving speeds. In an automobile intended for urban use, it is therefore advantageous when the majority of the power transistors contain silicon carbide, because these are more efficient than power transistors containing silicon for most of the intended use of the vehicle.

If the second power semiconductors, in particular power transistors, are only used with greater accelerations, they form a type of booster in a passing maneuver, or when driving uphill. Depending on the design, these can nevertheless form a greater portion of the inverter power. It is conceivable, for example, to increase the portion of second power transistors in sports cars, because more power is needed for acceleration in these vehicles. In this case, the actual current provided by the first power transistors may be greater than with the aforementioned automobile intended for urban use. Because there must be a large range available for acceleration, a proportionately larger number of second power diodes is needed.

In this case, in addition to the efficiency, cost may also be taken into account. Those power transistors that are only used briefly, can therefore be more economical. Even if these are less efficient, they can be used to provide an inexpensive means for obtaining brief power boosts. This has almost no impact on the overall performance.

The performance of the power electronics, in particular the inverter performance, referred to here is preferably the peak performance. This is normally determined in 10 second intervals. This therefore refers to the maximum performance of the power electronics over the course of ten seconds. As a matter of course, the ratio of power diodes can also be determined using other variables.

One design can comprise two types of power semiconductors, in particular power transistors, specifically power semiconductors that contain silicon and power semiconductors that contain silicon carbide. The power transistors containing silicon can be IGBTs and/or the power transistors containing silicon carbide can be MOSFETs.

The invention also relates to a half-bridge module for at least two topological switches. With this half-bridge module at least one of the topological switches has the design described above. Preferably all of the topological switches in the half-bridge module have the design described above. Preferably the two, or pairs of topological switches, are connected in series. One of the topological switches is then assigned to the negative pole of a battery, and the other topological switch is assigned to the positive pole.

This can also be referred to as a half-bridge topology. Two topological switches in a series form a topological half-bridge element. Numerous half-bridge elements can then be connected in parallel to form a half-bridge. A half-bridge is understood to be an actual component, which can also be purchased as such.

The invention also relates to a B6 module that has at least two half-bridges, each of which contains at least one half-bridge module. With this B6 module, at least one half-bridge module has the design described above. The B6 module is also understood to be topological. The half-bridges for one phase can contain numerous half-bridge modules in order to accommodate the amount of current passing through them. The number of half-bridges in an inverter, or a B6 module, corresponds to the number of phases that are to be generated. The individual half-bridges can also be composed of numerous half-bridge modules.

The topological switches in the half-bridge module preferably all have the same structure. The half-bridge modules also preferably all have the same structure. They only differ then in terms of the different phases to which they are assigned.

All of the half-bridges in the B6 module preferably have the design described above. The B6 module preferably has three half-bridges. The B6 module can also contain four half-bridges. The B6 module can also contain six half-bridges. The B6 module can also contain twelve half-bridges.

The invention also relates to an inverter that has that has at least two topological semiconductor switches, and/or at least one half-bridge module, and/or at least one B6 module. With this inverter, at least one of the topological switches, and/or the semiconductor package, and/or the half-bridge module, and/or the B6 module, have the designs described above.

The inverter can also contain a control board.

The inverter can also contain a power board. The semiconductor package, and/or half-bridge module, and/or B6 module can be placed thereon. Instead of a B6 module, the half-bridge module can also be a higher order module. The semiconductor packages can also be incorporated in higher order modules.

The inverter can also contain a current sensor. This can be used in particular to determine the strength of the alternating current that is output.

The inverter can also contain a cooler. This can be placed in a wall of the inverter, or inside the inverter.

The inverter can also contain a capacitor assembly. The capacitor assembly can contain numerous intermediate circuit capacitors.

The inverter can also have a plug for connecting the power lines and/or signal lines.

The inverter can also contain an EMC filter. This can be placed at the direct current end of the power lines. A filter can also be placed at the alternating current end of the power lines.

The invention also relates to an electric motor assembly that has at least one electric motor and one inverter. This electric motor assembly contains the inverter described above.

The electric motor assembly can preferably contain exactly one electric motor. The electric motor assembly can also contain at least two, in particular exactly two, electric motors. The inverter is preferably the only inverter in the electric motor assembly. The inverter described herein can also be used to operate two electric motors.

The invention also relates to a motor vehicle that has an electric motor assembly. This motor vehicle has the electric motor assembly described above.

The motor vehicle advantageously contain an electric axle, and the electric motor assembly can be dedicated to the electric axle.

The motor vehicle can also be a hybrid vehicle. It can therefore also contain at least one internal combustion engine. In this case, the electric motor assembly can be dedicated to the same axle as the internal combustion engine, or to a different axle.

The electric motor assembly can preferably be used in a motor vehicle with a single electric axle. This further increases the efficiency in hybrid vehicles, for example, because when the vehicle is being operated using only electricity, power transistors with optimal operating points for different driving situations are always available.

The inverters can be designed for voltage classes of 48V, 400V or 800V. The power diodes can have ratings for 80V, 120V, 650V, 750V, or 1200V, accordingly. This refers to the maximum cutoff voltage.

The motor vehicle also comprises a direct current source, e.g. at least one battery. This supplies direct current to the inverter, and/or is charged via the inverter.

The motor vehicle can also contain a fuel cell.

Further advantages, features, and details of the invention can be derived from the following description of exemplary embodiments and the drawings. Therein:

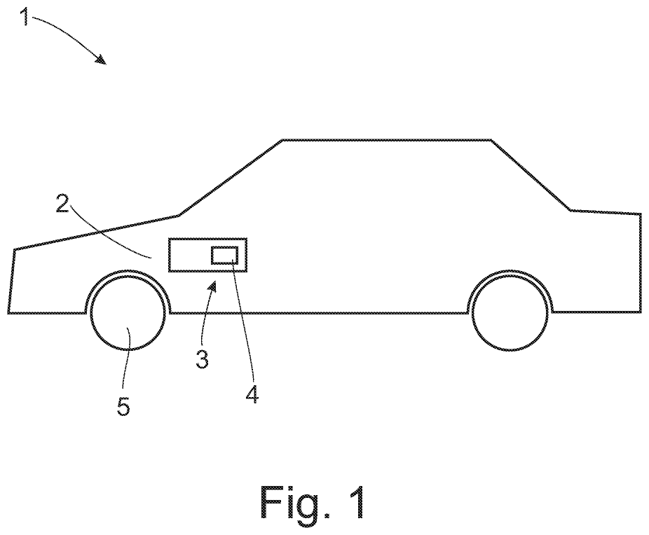

FIG. 1 shows a motor vehicle;

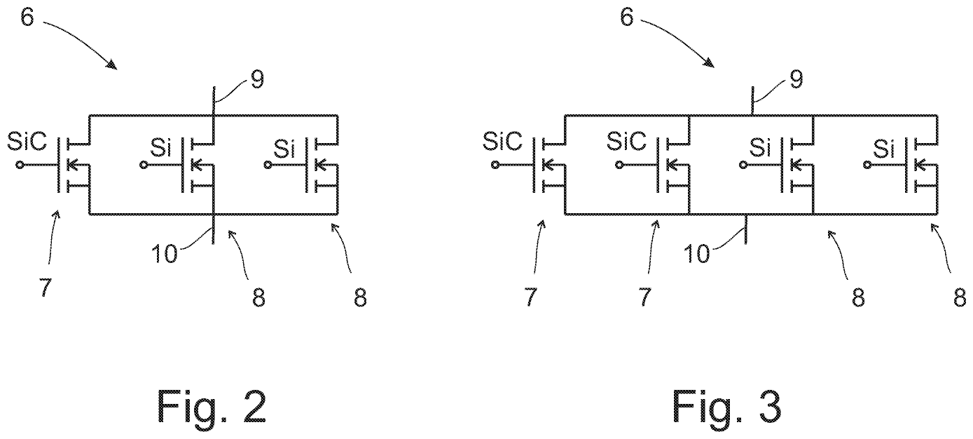

FIG. 2 shows a first design for a topological switch;

FIG. 3 shows a second design for a topological switch;

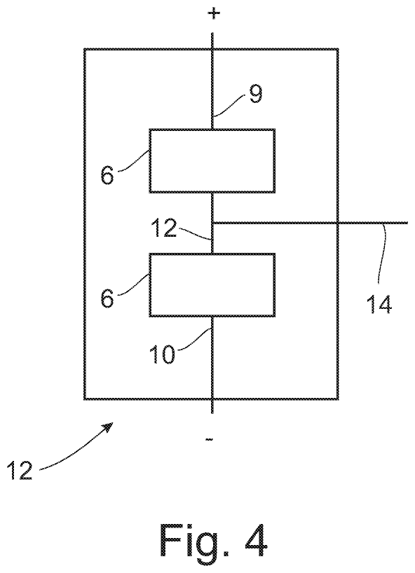

FIG. 4 shows a half-bridge module; and

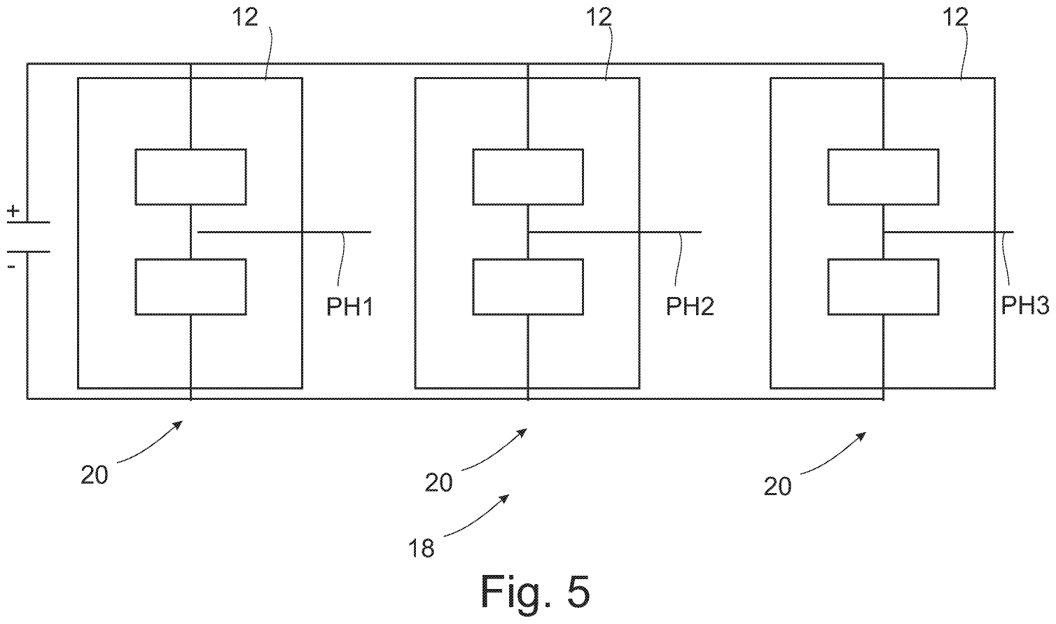

FIG. 5 shows a B6 module.

FIG. 1 shows a motor vehicle 1 that has power electronics 2, e.g. in the form of an inverter 3. This comprises a power module 4, among other things.

The motor vehicle 1 can contain an electric axle 5. The motor vehicle 1 can be either a hybrid motor vehicle or an electric vehicle. Particularly preferably, the motor vehicle 1 has a single electric axle.

The components of the power module 4 shall be described below starting at the “bottom” and progressing to the “top.”

FIG. 2 shows a topological switch 6 that has three power transistors, one of which is a MOSFET 7, and two of which are IGBTs 8. The MOSFET 7 preferably contains silicon carbide as its semiconductor material, and the IBGTs 8 contain silicon. If, purely by way of example, the topological switch is designed to process 300 A, the power transistors 7 and 8 must each be able to process 100 A. They are connected in parallel, for which reason the current load is additive.

It is clear that the number of power semiconductors, in particular power transistors 7 and 8, is not precisely determined in a topological switch 6. It is also clear, however, that there is a switching function between the input 9 and the output 10. This is obtained with the topological switch 6. The only critical part of its construction is that it has at least one first power semiconductor that contains a first semiconductor material and at least one second power semiconductor that contains a second semiconductor material, as described above. In this example, the first power semiconductor is the MOSFET 7, which contains the first semiconductor material SiC, and the second power semiconductors are two IGBTs 8, which contain the second semiconductor material Si. These semiconductor transistors, containing the indicated materials, are preferred, but the numbers thereof depend on the current loads, and are therefore merely exemplary.

Normally, a topological switch also has one diode for each transistor. For purposes of clarity, these are not shown.

FIG. 3 shows a modified topological switch 6 that contains four transistors, two of which are MOSFETs 7, and two of which are IGBTs 8. This illustrates the variability of a topological switch 6.

It should be noted that the power semiconductors can preferably be activated separately, regardless of their concrete designs and the design of the topological switch 6. This also means that they can all be activated simultaneously as well, or any combination of individual power semiconductors or each individual semiconductor can be activated separately.

FIG. 4 shows a half-bridge module 12. This contains two topological switches 6 connected in series. The input 9 is connected to the positive pole of a battery, and the output 10 is connected to the negative pole. A phase current in the phase line 16 can be tapped into at the connection 14. Each of the topological switches 6 can have the design shown in FIG. 2 or 3. Preferably, the topological switches 6 are identical to one another. This means that if the topological switch has four transistors at the positive side, it also has the same at the negative side. If there are two MOSFETs and two IGBTs at the negative side, then there are the same at the positive side.

The topological switch at the positive side is also referred to as the high-side switch, and the topological switch at the negative side is referred to as the low-side switch.

FIG. 5 shows a so-called B6 module 18. This has one half-bridge 20 for each phase PH1, PH2, PH3 for a multiphase electric motor. Depending on the current load, a half-bridge 20 can contain one half-bridge module 12, or two or more. A half-bridge 20 is therefore also a topology. Its function is to provide a phase current. With three phase currents, a B6 module 18 has three half-bridges 20, and therefore at least three half-bridge modules 12. The topological switches 6 in the half-bridge modules are preferably identical.

### REFERENCE SYMBOLS

1 motor vehicle
2 power electronics
3 inverter assembly
4 power module
5 electric axle
6 electric motor assembly
7 MOSFET
8 IBGT
9 input
10 output
12 half-bridge module
14 connection
16 phase
18 B6 module
20 half-bridge

1. A topological semiconductor switch for power electronics comprising:
at least two power semiconductors, in particular power transistors,
wherein at least one first power semiconductor of the at least two power semiconductors contains a first semiconductor material, and
at least one second power semiconductor of the at least two power semiconductors contains a second semiconductor material.

2. The topological semiconductor switch according to claim 1, characterized in that the at least two power semiconductors are connected to a negative pole of a battery or a positive pole of the battery.

3. The topological semiconductor switch according to claim 1, wherein there are a same number of first power semiconductors and second power semiconductors.

4. The topological semiconductor switch according to claim 1, wherein the first semiconductor material is silicon (Si).

5. The topological semiconductor switch according to claim 1, wherein the at least one first power semiconductor containing the first semiconductor material is an IGBT.

6. The topological semiconductor switch according to claim 1, wherein the second semiconductor material is silicon carbide (SiC).

7. The topological semiconductor switch according to claim 1, wherein the at least one second power semiconductor containing the second semiconductor material is a MOSFET.

8. A semiconductor package comprising the topological semiconductor switch according to claim 1.

9. A half-bridge module comprising the semiconductor package according to claim 8.

10. A B6 module comprising at least one half-bridge module according to claim 9.

11. An inverter comprising at least two topological semiconductor switches according to claim 1.

12. An electric motor assembly comprising at least one electric motor and the inverter according to claim 11.

13. A motor vehicle comprising the electric motor assembly according to claim 12.

14. The motor vehicle according to claim 13 comprising one electric axle.

15. The topological semiconductor switch according to claim 1, wherein the at least two power semiconductors are power transistors.

16. The topological semiconductor switch according to claim 4, wherein the second semiconductor material is silicon carbide (SiC).

17. The topological semiconductor switch according to claim 5, wherein the at least one second power semiconductor containing the second semiconductor material is a MOSFET.

18. The topological semiconductor switch according to claim 17,
wherein the first semiconductor material is silicon (Si), and
wherein the second semiconductor material is silicon carbide (SiC).

19. A half-bridge module comprising at least two topological semiconductor switches according to claim 1.
